(19) United States
(12) Patent Application Publication
(10) Pub. No.: US 2010/0127742 A1
(43) Pub. Date: May 27, 2010

(54) Frequency locked detecting apparatus and the method therefor

(75) Inventor: Chang-Yi Chen, Bade City (TW)

Correspondence Address: BACON & THOMAS, PLLC, 625 SLATERS LANE, FOURTH FLOOR, ALEXANDRIA, VA, 22314-1176, US

(73) Assignee: IdeaCom Technology Corporation, Hsin Tien (TW)

(21) Appl. No.: 12/382,508

(22) Filed: Mar. 18, 2009

(30) Foreign Application Priority Data
Nov. 21, 2008 (TW) 097145097

(51) Int. Cl. H03L 7/06

(52) U.S. Cl. 327/156

(57) ABSTRACT

The invention relates to a frequency locked detecting apparatus for detecting the frequency of an output frequency signal generated by a phase locked loop according to a input frequency signal, determining whether the phase locked loop is locked or not and generating a detecting signal correspondingly. The frequency detecting apparatus comprises an input module, a processing module, a decoding module and a control module. The inputting module generates an input signal and an enable signal according to a control signal, the input frequency signal and the output frequency signal. The processing module generates at least one processing signal corresponding to the input signal and the enable signal. The decoding module decodes at least one processing signal and generates a decoded signal. The control module generates the detecting signal according to the control signal, the enable signal and the decoded signal.

### BACKGROUND OF THE INVENTION

1. Field of the Invention

The invention is related to a frequency locked detecting apparatus, and more specifically related to a frequency locked detecting apparatus for automatically detecting whether the output signal of a phase locked loop (PLL) is locked or not.

2. Description of the Prior Art

In general, a phase locked loop (PLL) is used for controlling the frequency or the phase of electronic signal for the situation such as clock recovery, modulation, demodulation or frequency synthesis. In brief, the basic function of the PLL is for driving the adjustable frequency unit via the feedback of the control system loop by referring to an oscillator source with a very little frequency alteration. Therefore, the adjustable frequency unit can reach the frequency to a level as the same as the oscillator source in a fast, stable manner.

Please referring to FIG. 1, FIG. 1 is a schematic diagram of a conventional circuit of phase locked loop. As shown as FIG. 1, phase locked loop (PLL) 10 includes a phase frequency detector 12, a charge pump 14, a filter 16, a voltage control oscillator 18 and three frequency divider 11, 19 and 20. First frequency divider 11 divides the frequency of an input signal and generates a reference signal S_{REF}. Phase frequency detector 12 detects the difference between the reference signal S_{REF} and the frequency diving signal S_{DIV} feedback from frequency divider 20, and then outputs the compared result via two digital signals S_{F} and S_{L}. The charge pump 14 is used for converting the two digital signals S_{H} and S_{L} to a control voltage VC, and the filter 16 is used for filtering the high frequency of the control voltage VC and outputting it to the voltage control oscillator 18. The voltage control oscillator 18 transfers the control voltage VC to an oscillating signal S_{O}, and the frequency divider 20 adjusts the frequency of the oscillating signal S_{O} and feedbacks it to the phase frequency detector 12 to compare with the reference signal S_{REF}, and then adjusts the frequency of the oscillating signal S_{O}. The frequency divider 19 divides the frequency of the final oscillating signal S_{O} and generates the output signal. Some kinds of PLL don't include frequency divider 19. In other words, the frequency divider 19 is added if necessary.

When there is not a reference signal S_{REF} generated, phase frequency detector 12 outputs the digital signal (pull down signal) S_{L}. The charge pump 14 controls the control voltage VC to descend from an initial level when the digital signal S_{L} is received. The oscillating signal S_{O} of the voltage control oscillator 18 descends from its initial level in a manner corresponding to the descent of the control voltage VC. When the reference signal S_{REF} is regenerated, the charge pump 14 returns the original control voltage VC to the initial level so that the frequency of the oscillating signal S_{O} outputted by the voltage control oscillator 18 will thus return to its initial level. The operation is thus continued to accomplish the phase adjusting operation for PLL 10.

However, as the precision requirement of the electronic products enhances, the accuracy of various kinds of the electronic elements enhances accordingly. If there has any error in the phase locked loop, the frequency of the output signal has corresponding error, and that will affects the operation of the whole digital circuit

According to the defects of the prior art described above, how to provide a fast and convenient detecting method and apparatus for detecting whether the output signal of PLL locked or not, and how to control the operation of the digital circuit by the detected signal so as to prevent the error of PLL when the power is turned on from causing the deterioration of the digital circuit or even of the whole electronic product, are both becoming an important issue in the field.

### SUMMARY OF THE INVENTION

It is therefore a primary objective of the present invention to provide a frequency locked detecting apparatus and method for auto-detecting the output signal of the PLL is matched with a predetermined level, and generating a detecting signal according to the detected result to control the digital circuit thereafter.

One embodiment of the present invention provides a frequency locked detecting apparatus for detecting frequency of an output frequency signal according to an input frequency signal and generating a detecting signal correspondingly, the frequency locked detecting apparatus comprising an input module, a processing module, a decoding module and a control module. The input module is used for receiving the input frequency and the output frequency signal and generating an input signal and an enable signal according to a control signal, the input frequency signal and the output frequency signal. The processing module coupled to the input module for generating at least one processing signal according to the input signal and the enable signal. The decoding module coupled to the processing module for decoding the processing and generating a decoded signal. The control module coupled to the input module and the decoding module for generating the detecting signal according to the control signal, the enable signal and the decoded signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional circuit of phase locked loop.

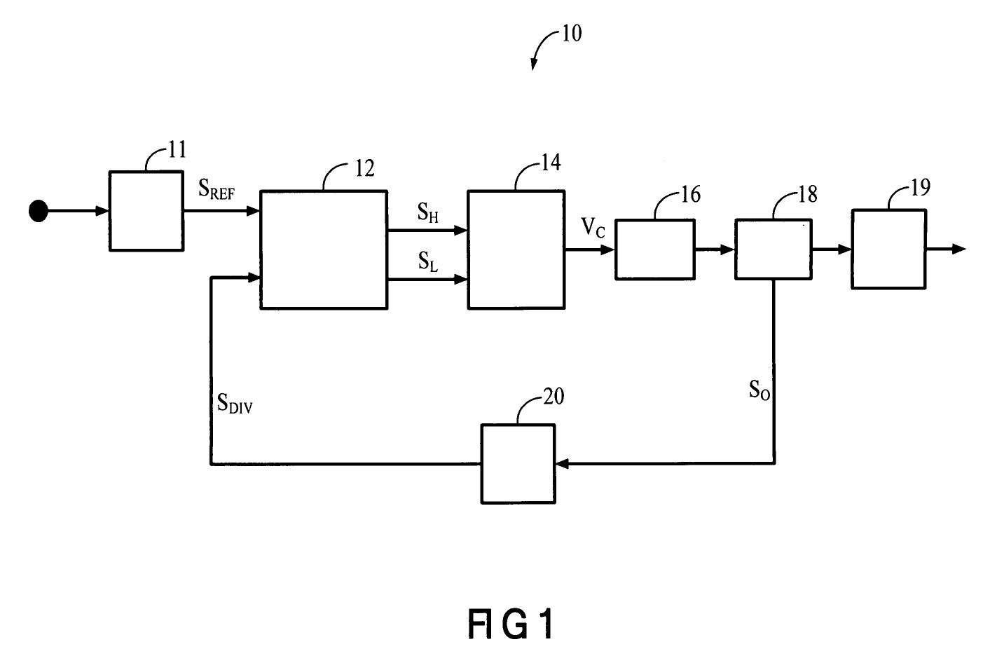

FIG. 2 is a schematic diagram of one embodiment of the frequency locked detecting apparatus and phase locked loop according to the present invention.

FIG. 3 is a schematic diagram of one embodiment of the frequency locked detecting apparatus according to the present invention.

FIG. 4 is a schematic diagram of one embodiment of the frequency locked detecting apparatus according to the present invention.

FIG. 5 is a schematic diagram of one embodiment of processing module of the frequency locked detecting apparatus and phase locked loop according to the present invention.

FIGS. 6A to 6C are schematic diagrams of one embodiment of signal of the frequency locked detecting apparatus according to the present invention.

FIG. 7 is a flowchart diagram of an embodiment of the frequency locked detecting method according to the present invention.

FIG. 8 is a flowchart diagram of an embodiment of the frequency locked detecting method to generate at least one processing signal according to the present invention.

### DETAILED DESCRIPTION

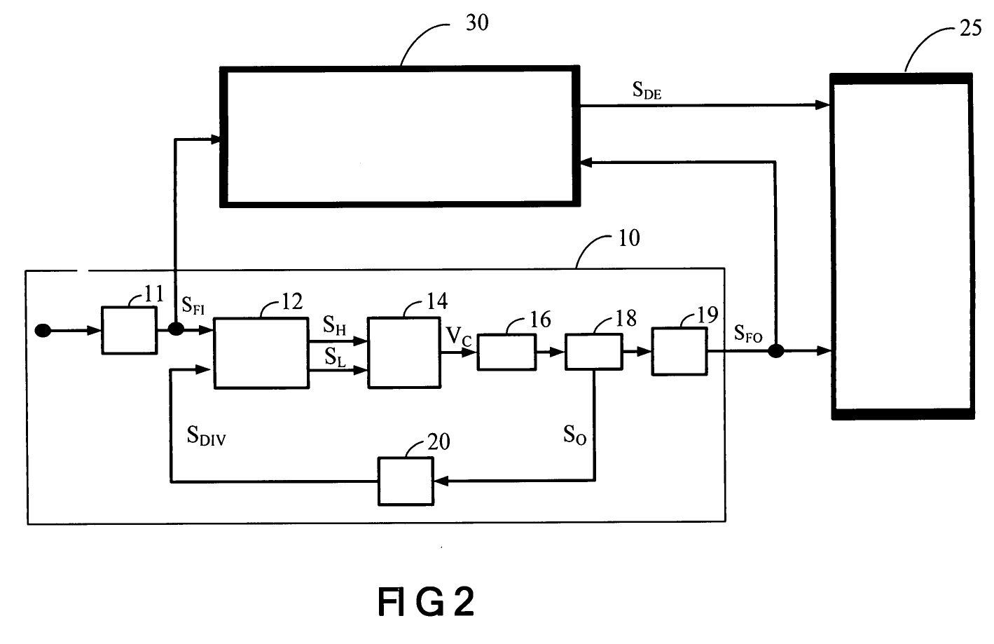

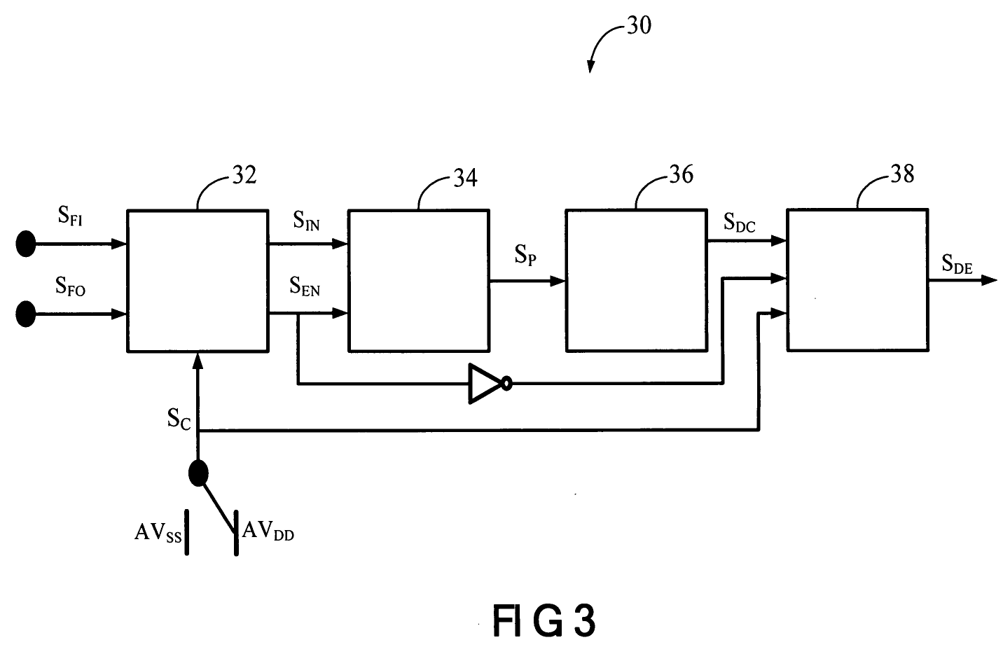

Please referring to FIG. 2 and FIG. 3, FIG. 2 is a schematic diagram of one embodiment of the frequency locked detecting apparatus and phase locked loop according to the present invention. FIG. 3 is a schematic diagram of one embodiment of the frequency locked detecting apparatus according to the present invention.

As shown in FIG. 2 and FIG. 3, the present invention is a frequency locked detecting apparatus 30 for detecting frequency of an output frequency signal S_{FO} according to an input frequency signal S_{FI} of a phase locked loop 10, generating a detecting signal S_{DE} correspondingly and then controlling a digital circuit 25 by the detecting signal S_{DE}. The input frequency signal S_{FI} is input signal inputted to the phase frequency detector 12 of the phase locked loop 10 and the output frequency signal SFO is the output signal via the frequency divided by the frequency divider 19 of the phase locked loop 10. When the level of the detecting signal S_{DE} in respect to the detected result matches with the predetermined value, the digital circuit 25 coupled to the frequency locked detecting apparatus 30 and the phase locked loop 10 executes the operation according to the output frequency signal S_{FO} generated by the phase locked loop 10, or if not the digital circuit 25 executes no operation. The digital circuit 25 executes the back end processing operation via the output frequency signal S_{FO} generated by the phase locked loop 10, but the operation is further determined by the detecting signal S_{DE} generated by the frequency locked detecting apparatus 30.

As shown as FIG. 3, the frequency locked detecting apparatus 30 comprising an input module 32, a processing module 34, a decoding module 36 and a control module 38. The input module 32 is used for receiving the input frequency signal S_{FI} and the output frequency signal S_{FO} and generating an input signal S_{IN} and a enable signal S_{EN} according to a control signal S_{C}, the input frequency signal S_{FI} and the output frequency signal S_{FO}. The processing module 34 coupled to the input module 32 is used for generating at least one processing signal S_{P} according to the input signal S_{IN} and the enable signal S_{EN}. The decoding module 36 coupled to the processing module 34 for decoding at least one processing S_{P} and generating a decoded signal S_{DC}. The control module 38 coupled to the input module 32 and the decoding module 36 is used for generating the detecting signal S_{DE} according to the control signal S_{C}, the enable signal S_{EN} and the decoded signal S_{DC}.

In one of the embodiments, the input frequency signal SFI of the phase locked loop 10 includes a first frequency and the output frequency signal S_{FO} includes a second frequency. The frequency locked detecting apparatus 30 detects whether the second frequency matches with the predetermined level setting according to the first frequency, and generates the detecting signal S_{DE} according to the detected result. For example, a user can preset the second frequency being 8 times or any other times the frequency of the first frequency, and then detects whether the second frequency reaching the preset times or not to generate the detecting signal S_{DE} with different level according to the detected result.

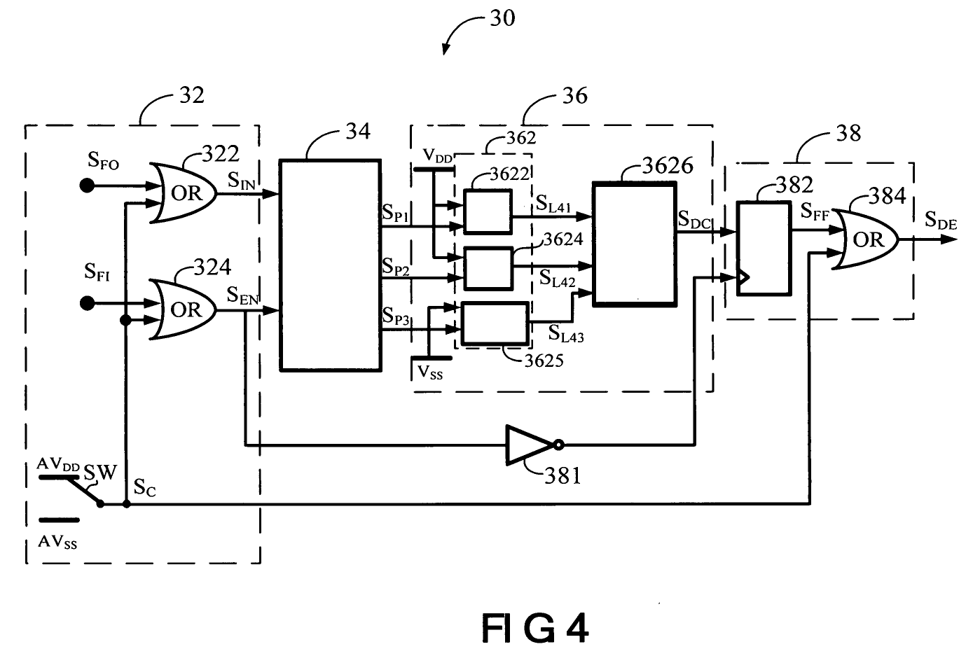

Please referring to the FIG. 4, FIG. 4 is a schematic diagram of one embodiment of the frequency locked detecting apparatus according to the present invention. As shown as the FIG. 4, the input module 32 includes a first logic unit 322 and a second logic unit 324, the first logic unit 322 executes a first logic operation with the output frequency signal S_{FO} and the control signal S_{C} of the phase locked loop 10, generates the input signal S_{IN} and outputs it to the processing module 34. The second logic unit 324 executes a second logic operation with input frequency signal S_{FI} and the control signal S_{C} to generate the enable signal S_{EN} used for controlling the processing module 34. In one embodiment, the first logic unit 322 and the second logic unit 324 is an OR gate and the corresponding first logic operation and the second logic operation is an OR operation respectively. The control signal SC is a signal generated by a power source or a ground. The frequency locked detecting apparatus 30 further includes a switch SW used for controlling the connection to the power source AVDD or ground AVSS by coupling between one of them.

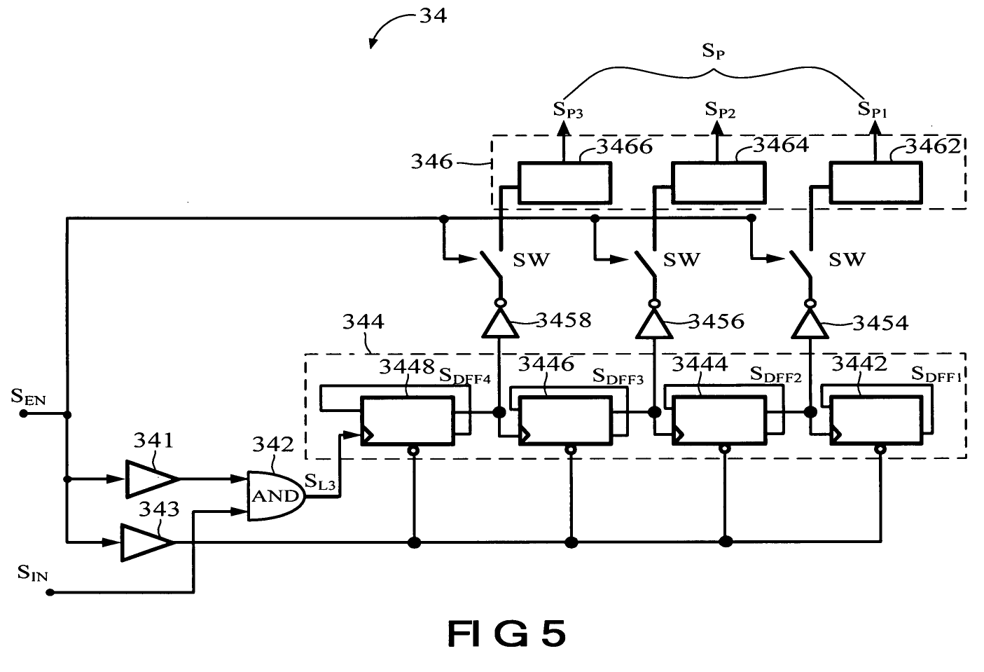

Please referring to the FIG. 4 and FIG. 5, FIG. 5 is a schematic diagram of one embodiment of processing module of the frequency locked detecting apparatus and phase locked loop according to the present invention. As shown in FIG. 4 and FIG. 5, the processing module 34 includes a third logic unit (AND gate) 342, at least one D flip-flop 344 and at least one latch 346. The third logic unit 342 executes a third logic operation with the enable signal S_{EN} and the input signal S_{IN} to generate a third logic signal SL3. At least one D flip-flop 344 coupled to the third logic unit 342 starts counting according to the enable signal S_{EN} when received the third logic signal S_{L3} to generate at least one D flip-flop signal S_{DFF} (S_{DFF1}˜S_{DFF4}). At least one latch 346 coupled to at least one D flip-flop 344 latches at least one D flip-flop signals S_{DFF} (S_{DFF1}˜S_{DFF4}) to generate at least one processing signal S_{P} (S_{P1}˜S_{P3}). There are at least one switch SW and a inverter (3454, 3456 and 3458), at least one switch SW turns on or off respectively according to the enable signal S_{EN} to control whether at least one D flip-flop 344 connects to at least one latch 346 or not. The inverter (3454, 3456 and 3458) is used for inversing at least one D flip-flop signal S_{DFF} (S_{DFF1}˜S_{DFF4}) and inputting the inversed at least one D flip-flop signal S_{DFF} to at least one latch 346 according to the control of at least one switch SW. There is a third first buffer coupled between the input module 32 and the third logic unit 342 for buffering the enable signal S_{EN}. There is a third second buffer 342 coupled between the input module 32 and at least one D flip-flop 344 for buffering the enable signal S_{EN} and resetting at least one D flip-flop 344 according to the buffered enable signal S_{EN}.

The decoding module 36 includes at least one fourth logic unit 362 coupled to the processing module 34 and a power source VDD for executing at least one fourth logic operation with at least one processing signal S_{P} (S_{P1}˜S_{P3}) to generate the decoded signal S_{DC}. When user set the second frequency of the output frequency signal S_{FO} is 4 times of level of the first frequency of the input frequency signal S_{FI}, at least one processing signal S_{P} of the frequency locked detecting apparatus 30 includes a first processing signal S_{P1}, at least one second processing signal S_{P2} and at least one third processing signal S_{P3}. In this condition, the level of the received processing signal S_{P1}, S_{P2} and S_{P3} of the three fourth logic units 364 are “011”. According to the logic operation, it needs two processing signals S₁ and S_{P2} under the 4 times condition, but in order to confirm the error cause by the fast frequency of the signal in the actual implement. So even if the processing signal Sp3 is the level of “0”, the decoding module 36 also utilized three fourth logic unit 362 to execute the operation and uses the processing signal S_{P} to determine whether the frequency too fast or not.

In the embodiment of the second frequency as 4 times of the level of the first frequency, at least one fourth logic unit 362 are at least one fourth first logic unit (AND Gate) 3622 and 3624, a fourth second logic unit (NOR gate) 3625 and a fourth fifth logic unit (AND gate) 3626. At least one fourth first logic unit (3622, 3624) includes a first fourth first logic unit 3622 and a second fourth first logic unit 3624, the two fourth first logic unit (3622, 3624) coupled to the processing module 34 and the voltage source AVDD respectively are used for executing a fourth first logic operation with the first processing signal S_{P1} and second processing signal S_{P2} to generate two fourth first logic signals S_{L41} and S_{L42}. The fourth second logic unit 3625 coupled to the processing module 34 and the ground AVSS is used for executing a fourth second logic operation (NOR operation) with the third processing signal S_{P3} to generate fourth second logic signal S_{L43}. The fourth fifth logic unit 3626 coupled to the two fourth first logic unit 3622 and the fourth second logic unit 3625 executes a fourth fifth logic operation (AND operation) with those two fourth first logic signal S_{L41} and S_{L42} and at least one fourth second logic signal S_{L43} to generate the decided signal SDC. When the level of at least one processing signal S_{P} is “High”, the logic unit coupled in the back end is a AND gate to execute the logic operation as shown as those two fourth first logic unit (3622, 3624). If the level of at least one processing signal S_{P} is “LOW”, the logic unit coupled in the back end is a NOR gate to execute the logic operation as shown as the fourth second logic unit 3625.

The control module 38 includes a flip-flop 382 and a fifth logic unit 384, the flip-flop 382 coupled to the input module 32 and the decoding module 36 for controlling the storage or output decoded signal S_{DC} according to the enable signal S_{EN} to generate a flip-flop signal S_{FF}. The fifth logic unit 384 coupled to the flip-flop 382 and the input module 32 is used for executing a fifth logic operation with the flip-flop signal S_{FF} and the control signal S_{C} to generate the detecting signal S_{DE}. There is an inverter 381 coupled between the flip-flop 382 and the input module 32 to inverse the enable signal S_{EN}.

The following description is used for explaining the operation of the processing module 34, the decoding module 36 and the control module 38, the processing module 34 utilized at least one D flip-flop 344 to execute a counting operation for counting the numbers of the inputted input signal S_{IN} when the level of the enable signal S_{EN} is “HIGH” and then outputs the counting result to at least one latch 346 synchronous. When the level of the enable signal S_{EN} is “LOW”, the third second buffer 343 controls at least one switch SW turning off and holding the counting numbers of the D flip-flop 344, and executes a reset operation to start counting the numbers again until it storing the numbers to the latch 346. The determined level can be set as a parameter by user according to the actual implement which can be the specific times that the second frequency divided by the first frequency. If the decoded result of the decoding module 35 is the same as the parameter, the level of the decoded signal S_{DC} output by the decoding module 35 is “HIGH” to respect that the phase locked loop has been locked, otherwise, the level of the output decoded signal S_{DC} is “LOW” to respect that the phase locked loop 10 has not been locked.

The control module 38 is controlled by the enable signal S_{EN} of the input module 32, when the control signal S_{C} with a high voltage level, the processing module 34 and the decoding module 36 is working in a normal mode, due to the operation mode of the control module 38 is control by a rising edge trigger, the output signal is keeping to the last voltage level. When the control signal S_{C} with a low voltage level, the processing module 34 and the decoding module 36 execute a reset operation mode and the control module 38 stores the decoded result of the decoding module 36 and outputs the detecting signal S_{DE}.

It must be noticed that the number of at least one D flip-flop 344, switch SW and latch 346 of the processing module 34 is corresponding to the preset times that the second frequency of the output frequency signal S_{FO} of the first frequency of the input frequency signal, for example when the second frequency is 2 times of the first frequency, the processing module 34 includes two D flip-flops (3442, 3444), two switches SW and two latches 3462 to generate one processing signal S_{P1}. When user sets the second frequency is 4 times of the first frequency, the processing module 34 includes three D flip-flops (3442, 3444 and 3446), three switches SW and three latches (3462 and 3464) to generate three processing signals (SP1, SP2 and SP3). Furthermore, the numbers of the fourth first logic unit (3622 and 3624) is corresponding to the number of the processing signal S_{P}, the real numbers of the fourth first logic unit just need the numbers of the processing signal S_{P} subtract one that can complete the decoding operation to generate the decoded signal S_{DC}. When the second frequency is 2^{N} of the first frequency, the numbers of the D flip-flop 344, the switch SW and the latch 346 is N+1 respectively. If the second frequency is not even times of the first frequency, for example, the times is in the range of 2^{N-1} and 2^{N}, the processing module 34 also needs including N+1 D flip-flop 344, switch SW and latch 346 respectively to complete the decoding operation.

It must be emphasized that the numbers of the processing module 34 and the decoding module 36 is corresponding to the relation of the second frequency and the first frequency, so user can set the numbers of element according to the real situation. The embodiment described above just used to explaining the operations of the phase locked detecting apparatus but not limited to other embodiment. Besides, the kinds of the related logic unit can be changed by the user according to the real implement, any kinds set of the logic unit can execute the operations and generate the processing signal S_{P} and the decoding signal S_{DC} which can be used as the processing module 34 and the decoding module 36 in the frequency locked detecting apparatus 30.

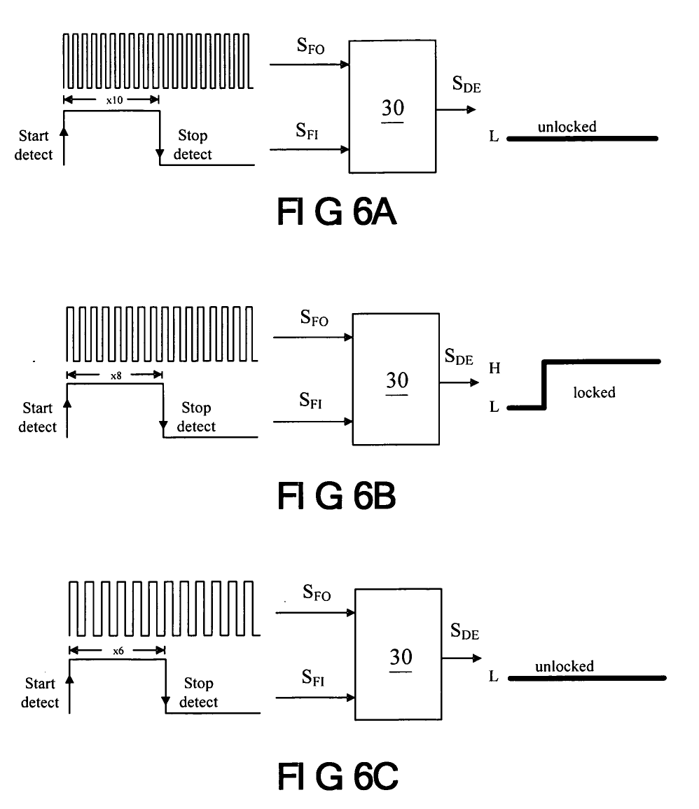

Please referring to the FIGS. 6A to 6C, FIGS. 6A to 6C are schematic diagrams of one embodiment of signal of the frequency locked detecting apparatus according to the present invention. After comparing the output frequency signal S_{FO} with the input frequency signal S_{FI} of the phase locked loop 10, the frequency locked detecting apparatus 30 determines whether the compared result the same as the parameter of the decoding module 36, if yes, it respects to that the phase locked loop 10 has been locked, the detecting signal S_{DE} is a signal with high level voltage drop used to control the digital circuit 25 at the back end.

If the first frequency of the input frequency signal S_{FI} is 6 MHz and the second frequency of the output frequency signal S_{FO} operated by the divider 19 is 48 MHz, taking the parameter of the decoding module 36 of the frequency locked detecting apparatus 30 is 8 (48/6=8) for example to explain the operation of the frequency locked detecting 30 according to the present invention. FIG. 6A is the exemplification for the frequency of the output frequency signal S_{FO} is too fast, in this embodiment, the second frequency is 10 times of the first frequency, so that the frequency locked detecting apparatus 30 determines the frequency doesn't match the setting of the decoding module 36 (because the setting parameter is 8 times), in this situation, the frequency locked detecting apparatus 30 outputs the detecting signal S_{DE} with low voltage level to determines the phase locked loop has not been locked. FIG. 6C is the exemplification for the frequency of the output frequency signal S_{FO} is too slow, in this embodiment, the second frequency is 6 times of the first frequency, the frequency locked detecting apparatus 30 also outputs the detecting signal S_{DE} with low voltage level to determines the phase locked loop has not been locked. FIG. 6B is the exemplification for the frequency of the output frequency signal S_{FO} is normal, in this embodiment, the second frequency is 8 times of the first frequency, so that the it match the preset parameter of the decoding module 36, therefore the frequency locked detecting apparatus 30 outputs the detecting signal S_{DE} with high voltage level to determines the phase locked loop has been locked.

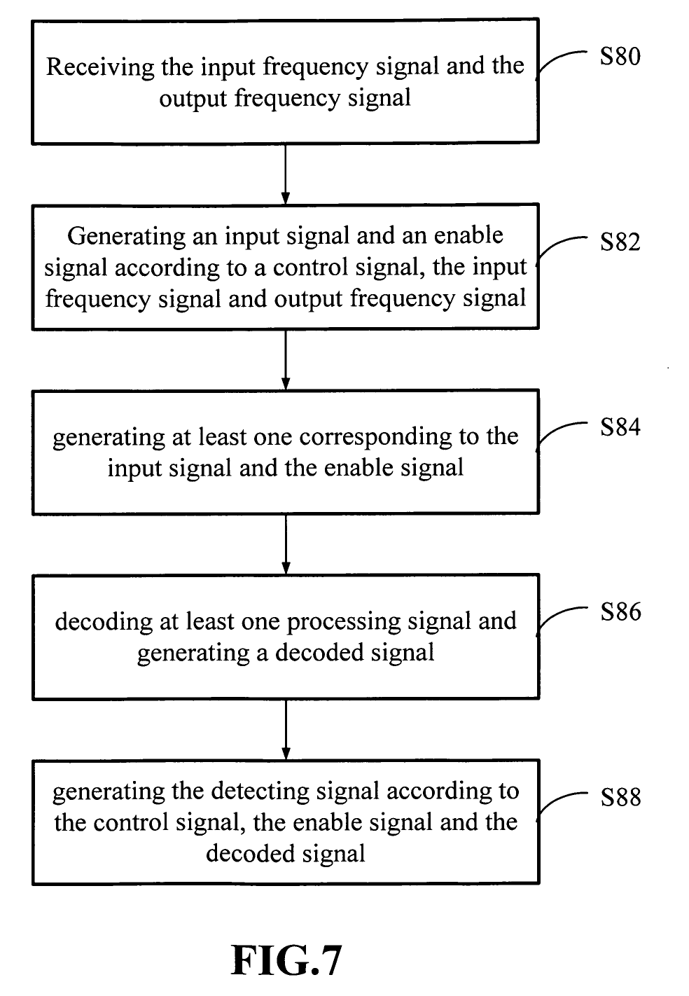

Please referring to the FIG. 7, FIG. 7 is a flowchart diagram of an embodiment of the frequency locked detecting method according to the present invention. As shown as the FIG. 7, the present invention is a frequency locked detecting method for detecting frequency of an output frequency signal according to an input frequency signal and generating a detecting signal correspondingly. The output frequency signal is the output signal generated by executing a locking operation via by a phase locked loop according to the input frequency signal, the input frequency signal includes a first frequency and the output frequency signal includes a second frequency. The frequency locked detecting method comprises the following steps:

S80: Receiving the input frequency signal and the output frequency signal;

S82: Generating an input signal and an enable signal according to a control signal, the input frequency signal and output frequency signal. In one of embodiment, this step executing a first logic operation with the output frequency signal and the control signal to generate the input signal, executing a second logic operation with the input frequency signal and the control signal to generate the enable signal. Furthermore the first logic operation is and the second logic operation is an OR operation respectively. The control signal is power source signal or a ground signal.

S84: generating at least one corresponding to the input signal and the enable signal;

S86: decoding at least one processing signal and generating a decoded signal. Wherein the executing at least one fourth logic operation with at least one processing signal to generate the decoded signal. In one of the embodiment, at least one processing signal includes at least one first processing signal and a second processing signal, this step executes at least one fourth first logic operation with at least one first processing signal to generate at least one fourth first logic signal, executes a fourth second logic operation with the second processing signal to generate a fourth second logic signal and executes a fourth fifth logic operation with at least one fourth first logic signal and the fourth second logic signal to generate the decoded signal. In the embodiment, the fourth first logic operation and the fourth fifth operation is a AND operation respectively and at least one fourth second logic operation is a NOR operation.

S88: generating the detecting signal according to the control signal, the enable signal and the decoded signal. Wherein this step controls the storage or output the decoded signal according to the enable signal to generate a flip-flop signal, and executes a fifth logic operation with the flip-flop signal and the control signal to generate the detecting signal. In the embodiment, the step of generating the flip-flop signal includes inversing the enable signal and adjusting the decoded signal according to the inversed enable signal to generate the flip-flop signal.

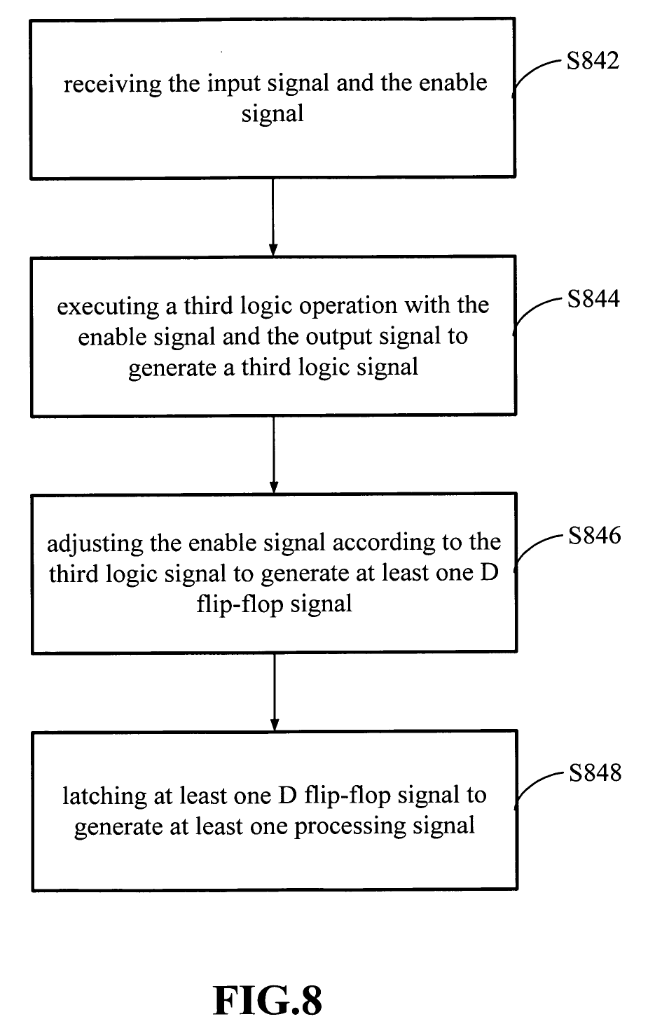

Please referring to the FIG. 8, FIG. 8 is a flowchart diagram of an embodiment of the frequency locked detecting method to generate at least one processing signal according to the present invention. As shown as FIG. 8, the step S84 further includes the following steps:

S842: receiving the input signal and the enable signal;

S844: executing a third logic operation with the enable signal and the output signal to generate a third logic signal. in one of embodiment, this step buffering the enable signal and the executing the third logic operation with the buffered enable signal and the input signal to generate the third logic signal, the third logic operation is an AND operation.

S846: adjusting the enable signal according to the third logic signal to generate at least one D flip-flop signal.

S848: latching at least one D flip-flop signal to generate at least one processing signal. This step further includes: buffering the enable signal and then resetting the D flip-flop signal according to the buffered enable signal.

As mentioned above, the present invention provides a frequency locked detecting apparatus and method comparing the input frequency signal with the output frequency signal of the phase locked loop according to the predetermined condition set by user. If the compared result matches the predetermined condition, the frequency locked detecting apparatus will output the output signal and a detecting signal to the back end digit circuit to execute further operation. So that it can prevent from the error operating of the back end digital circuit caused by the inaccuracy or the offset of the output frequency signal. Comparing with the phase locked loop without the frequency locked detecting apparatus of present invention in the conventional circuit, the frequency locked detecting apparatus and method can auto detects whether the phase locked loop has been locked or not quickly and controls the operation of the digital circuit via the detecting signal which can prevent the back end digital circuit from error operating.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A frequency locked detecting apparatus for detecting frequency of an output frequency signal according to an input frequency signal and generating a detecting signal correspondingly, the frequency locked detecting apparatus comprising:
an input module for receiving the input frequency signal and the output frequency signal and generating an input signal and an enable signal according to a control signal, the input frequency signal and the output frequency signal;
a processing module coupled to the input module for generating at least one processing signal according to the input signal and the enable signal;
a decoding module coupled to the processing module for decoding the processing and generating a decoded signal; and
a control module coupled to the input module and the decoding module for generating the detecting signal according to the control signal, the enable signal and the decoded signal.

2. The frequency locked detecting apparatus of claim 1, wherein the input frequency signal includes a first frequency and the output frequency signal includes a second frequency.

3. The frequency locked detecting apparatus of claim 1, wherein the input module comprises:
a first logic unit for executing a first logic operation with the output frequency signal and the control signal to generate the input signal; and
a second logic unit for executing a second logic operation with the input frequency signal and the control signal to generate the enable signal.

4. The frequency locked detecting apparatus of claim 1, wherein the processing module comprises:
a third logic unit for receiving the input signal and the enable signal and then executing a third logic operation with the enable signal and the input signal to generate a third logic signal;
at least one F flip-flop coupled to the third logic unit for receiving the third logic signal and counting to generate at least one D flip-flop signal; and
at least one latch coupled to at least one D flip-flop for latching at least one D flip-flop signal and generating at least one processing signal.

5. The frequency locked detecting apparatus of claim 4, wherein at least one switch between at least one D flip-flop and at least one latch is used for turning on or off selectively controlled by the enable signal for controlling at least one D flip-flop connected to at least one latch.

6. The frequency locked detecting apparatus of claim 5, wherein a third second buffer between the input module and at least one D flip-flop is used for buffering the enable signal and further reset the D flip-flop according to the buffered enable signal.

7. The frequency locked detecting apparatus of claim 3, wherein the decoding module comprises:
at least one fourth logic unit coupled to the processing module and a voltage source for executing a fourth logic operation with at least one processing signal to generate the decoded signal.

8. The frequency locked detecting apparatus of claim 7, wherein at least one processing signal includes at least one first processing signal and a second processing signal, at least one fourth logic unit comprising:
at least one fourth first logic unit coupled to the processing module and the voltage source for executing at least one fourth first logic operation with at least one first processing signal to generate at least one fourth first logic signal;
a fourth second logic unit coupled to the processing module and a ground terminal for executing a fourth second logic operation with the second processing signal to generate a fourth second logic signal; and
a fourth fifth logic unit coupled to at least one fourth first logic unit and the fourth second logic unit for executing a fourth fifth logic operation with at least one fourth first logic signal and the fourth second logic signal to generate the decoded signal.

9. The frequency locked detecting apparatus of claim 1, wherein the control module comprises:
a flip-flop coupled to the input module and the decoding module for adjusting the decoded signal according to the enable signal to generate a flip-flop signal; and
a fifth logic unit coupled to the flip-flop and the input module for executing a fifth logic operation with the flip-flop signal and the control signal to generate the detecting signal.

10. The frequency locked detecting apparatus of claim 9, wherein an inverter between the flip-flop and the input module is used for inversing the enable signal.

11. The frequency locked detecting apparatus of claim 1, wherein the output frequency signal is the output signal generated by locking the input frequency signal executed by a phase locked loop.

12. A frequency locked detecting method for detecting frequency of an output frequency signal according to an input frequency signal and generating a detecting signal correspondingly, which comprising the following step:
(a) receiving the input frequency signal and the output frequency signal;
(b) generating an input signal and an enable signal according to a control signal, the input frequency signal and output frequency signal;
(c) generating at least one corresponding to the input signal and the enable signal;
(d) decoding at least one processing signal and generating a decoded signal; and
(e) generating the detecting signal according to the control signal, the enable signal and the decoded signal.

13. The frequency locked detecting method of claim 12, wherein the input frequency signal with a first frequency and the output frequency signal with a second frequency.

14. The frequency locked detecting method of claim 12, wherein the step (b) includes the following steps:
(b1) executing a first logic operation with the output frequency signal and the control signal to generate the input signal; and
(b2) executing a second operation with the input frequency signal and the control signal to generate the enable signal.

15. The frequency locked detecting method of claim 12, wherein the step (c) includes the following steps:
(c1) receiving the input signal and the enable signal;
(c2) executing a third operation with the enable signal and the input signal to generate a third logic signal;
(c3) adjusting the enable signal according the third logic signal to generate at least one D flip-flop signal; and
(c4) latching at least one D flip-flop signal to generate at least one processing signal.

16. The frequency locked detecting method of claim 15, wherein the step (c2) further includes the following steps:
(c21) buffering the enable signal; and
(c22) executing the third operation with the buffered enable signal and the input signal to generate the third logic signal.

17. The frequency locked detecting method of claim 16, wherein the step (c) further includes the following step:
(c5) buffering the enable signal and resetting the D flip-flop signal according to the buffered enable signal.

18. The frequency locked detecting method of claim 12, wherein the step (d) executing at least one fourth operation with at least one processing signal to generate the decoded signal.

19. The frequency locked detecting method of claim 18, wherein at least one processing signal includes at least one first processing signal and a first processing signal, the step (d) includes the following steps:
(d1) executing a fourth first operation with at least one first processing signal and generating at least one fourth first logic signal;
(d2) executing a fourth first operation with the second processing signal to generate a fourth second logic signal; and
(d3) executing a fourth fifth operation with at least one fourth first logic signal and the fourth second logic signal to generate the decoded signal.

20. The frequency locked detecting method of claim 12, wherein the step (e) includes the following steps:
(e1) storing or outputting the enable signal to generate a flip-flop signal; and
(e2) executing a fifth logic signal with the flip-flop signal and the control signal to generate the detecting signal.

21. The frequency locked detecting method of claim 20, wherein the step (e1) includes the following steps:
(e11) inversing the enable signal; and
(e12) storing and outputting the decoded signal according to the inversed enable signal to generate the flip-flop signal.

22. The frequency locked detecting method of claim 12, wherein the output frequency signal is the output signal generated by locking the input frequency signal executed by a phase locked loop.
